(19) United States
(12) Patent Application Publication
(10) Pub. No.: US 2006/0006517 A1
(43) Pub. Date: Jan. 12, 2006

(54) Multi-chip package having heat dissipating path

(76) Inventors: Jin-Yang Lee, Gyeonggi-do (KR); Sang-Wook Park, Gyeonggi-do (KR); Hae-Hyung Lee, Gyeonggi-do (KR); Dong-Ho Lee, Gyeonggi-do (KR); Joong-Hyun Baek, Gyeonggi-go (KR)

Correspondence Address: MARGER JOHNSON & MCCOLLOM, P.C., 210 SW MORRISON STREET, SUITE 400, PORTLAND, OR, 97204, US

(21) Appl. No.: 11/176,800

(22) Filed: Jul. 6, 2005

(30) Foreign Application Priority Data
Jul. 8, 2004 (KR) 2004-52984

(51) Int. Cl. H01L 23/02

(52) U.S. Cl. 257/686

(57) ABSTRACT

A multi-chip package having a heat dissipating path. The multi-chip package includes a stack of integrated circuit (IC) chips, a heat sink part interposed between the IC chips so that one end portion of the heat sink part can be exposed from a side of the stack of integrated circuit chips, a substrate on which the stack of integrated circuit chips is mounted, and solder or solder ball-shaped thermally connecting parts to thermally connect the exposed end portion of the heat sink part to the substrate to dissipate heat collected in the heat sink part through the substrate.

### BACKGROUND OF THE INVENTION

This application claims the priority of Korean Patent Application No. 2004-52984, filed on Jul. 8, 2004, in the Korean Intellectual Property Office, the disclosure of which is incorporated herein in its entirety by reference.

1. Field of the Invention

The present invention relates to an integrated circuit (IC) chip package, and more particularly, to a multi-chip package (MCP) in which at least two IC chips are stacked.

2. Description of the Related Art

Many methods have been suggested in semiconductor manufacturing technology to package semiconductor integrated circuits (ICs), or IC chips. Some IC chip packaging technology demands very thin chips of tens of μm to achieve high density integration. To meet the demand, very thin chips or packages are suggested to be stacked. For example, there is an approach to a multi-chip package where semiconductor chips or IC chips are stacked to achieve high density integration.

FIG. 1 is a schematic sectional view illustrating a conventional MCP.

Referring to FIG. 1, in the conventional MCP, at least two IC chips 31 and 35 are embedded in one package. As shown in FIG. 1, the MCP contains the IC chips 31 and 35 stacked on a substrate 10, such as a printed circuit board (PCB). Metal lines, such as connection pads 21, are disposed on the substrate 10. The connection pads 21 are electrically connected to solder balls 27, which may be attached under the substrate 10, through ball pads 28. Gold wires or bonding wires 23 and 25 may be connected to the connection pads 21 to electrically connect bonding pads 29 of the IC chips 31 and 35 to the connection pads 21.

The lower chip, that is, the first chip 31, is adhered to the substrate 10 by a first adhesive layer 41, and the second chip 35 is adhered to the first chip 31 by a second adhesive layer 45. The second adhesive layer 45 may function as a spacer for keeping the first chip 31 and the second chip 35 spaced apart from each other. An encapsulating part 50 for protecting the stacked chips 31 and 35 and the bonding wires 23 and 25 is formed by a molding process using an encapsulating material, such as an epoxy molding compound (EMC).

The conventional MCP may have a problem with heat that may be trapped between the first chip 31 and the second chip 35. Heat generated during the operation of the first chip 31 and the second chip 35 should be dissipated through the solder balls 27 that are outwardly exposed. It is not easy for heat to be dissipated from a portion between the first chip 31 and the second chip 35, that is, the region of the second adhesive layer 45. Thus, heat may be trapped in the second adhesive layer 45.

Such heat trapping may occur because the conventional MCP shown in FIG. 1 has a limitation in dissipating heat. Heat trapped between the chips 31 and 35 should be transferred or dissipated through a heat dissipating path composed of the encapsulating part 50, the PCB substrate 10, and the solder balls 27. However, the heat dissipating path in the conventional MCP shown in FIG. 1 is very poor at heat transfer ability.

The heat trapped between the chips in the conventional MCP may result in a temperature rise of the package and an unwanted failure. In particular, when the conventional MCP including a high speed and high density chip product is applied to a mobile system, the temperature of the package increases during operation and the temperature rise leads to a decrease in the stability of junctions in chips. Consequently, chip product characteristics, for example, refresh characteristics, operating speed, and life time, may deteriorate.

Therefore, to secure a heat dissipating path that can effectively transfer and dissipate heat trapped between chips in an MCP is considered important in using the MCP.

### SUMMARY OF THE INVENTION

The present invention provides a thermally enhanced multi-chip package (MCP) having a heat dissipating path, which effectively transfers or dissipates heat generated during the operation of at least two stacked chips.

According to an aspect of the present invention, there is provided a multi-chip package comprising: a stack of integrated circuit chips; a heat sink part interposed between the integrated circuit chips so that at least one end portion can be exposed from at least a side of the stack of integrated circuit chips; a substrate on which the stack of integrated circuit chips is mounted; and a thermally connecting part to thermally connect the exposed end portion of the heat sink part to the substrate to dissipate heat collected in the heat sink part through the substrate.

Similarly, the heat sink part may be made of one selected from the group consisting of a copper plate, a metal plate, a silicon plate, a metal foil, a copper foil, a silicon plate coated with a metal layer, and a silicon plate coated with a copper layer.

The substrate may further comprise: a heat transfer pad connected to the thermally connecting parts; and a connecting solder ball thermally connected to the heat transfer pad and attached to the substrate to be connected to an external circuit.

A plurality of thermally connecting parts may be arranged along a side of the stack of integrated circuit chips on the substrate.

The thermally connecting parts may comprise solder balls attached to the exposed end portions of the heat sink part and attached to the heat transfer pads. The end portions of the heat sink part may have ball lands selectively opened so that the solder balls can be self-aligned and attached to the end portions. The ball lands may be open copper areas surrounded by an aluminum layer.

The heat sink part may comprise: a copper plate; and a printed solder resist film formed on the end portions of the copper plate and opening the ball lands on a surface of the copper plate so that the solder balls can be self-aligned and selectively attached to the end portions.

The heat sink part may comprise: a silicon plate; an aluminum layer deposited on the silicon plate; and a copper layer deposited on the end portions of the silicon plate and including ball lands in which the solder balls are self-aligned and selectively attached to the end portions.

Additionally, the heat sink part may comprise: a silicon plate; a copper layer deposited on the silicon plate; and an aluminum layer selectively deposited on the copper layer at the end portions of the silicon plate and opening the ball lands on a surface of the copper layer so that the solder balls can be self-aligned and selectively attached to the end portions.

The thickness of the heat sink part may range from 50 to 120 μm.

The thermally connecting parts may comprise solder parts formed by injecting solder paste between the exposed end portions of the heat sink part and the heat transfer pads and performing a reflow process.

The substrate may further comprise connecting solder balls attached to the substrate to be connected to an external circuit, wherein the heat transfer pads are electrically and thermally connected to grounding solder balls among the connecting solder balls. The thermally connecting parts may be arranged in two rows along side surfaces of the stack of integrated circuit chips on the substrate near to the sides of the stack of integrated circuit chips.

The multi-chip package has a heat dissipating path, which can effectively transfer and dissipate heat generated during the operation of the stacked at least two chips to the outside of the package, to enhance thermal performance.

### BRIEF DESCRIPTION OF THE DRAWINGS

The above and other features and advantages of the present invention will become more apparent by describing in detail exemplary embodiments thereof with reference to the attached drawings.

FIG. 1 is a schematic sectional view illustrating a conventional multi-chip package (MCP).

FIG. 2 is a schematic perspective view illustrating an MCP according to an embodiment of the present invention.

FIG. 3 is a schematic sectional view illustrating the MCP shown in FIG. 2.

FIG. 4 is a schematic sectional view illustrating a ball-shaped thermally connecting part employed in an MCP according to another embodiment of the present invention.

FIG. 5A and FIG. 5B are schematic sectional views illustrating a method of forming thermally connecting parts by solder reflow, which are employed in an MCP according to still another embodiment of the present invention.

FIGS. 6 through 8 are schematic perspective views illustrating examples of heat sink parts employed in the MCP according to embodiments of the present invention.

FIG. 9 is a schematic sectional view illustrating thermally connecting parts employed in an MCP according to yet another embodiment of the present invention.

FIG. 10 is a schematic sectional view illustrating an MCP having three stacked chips according to a further embodiment of the present invention.

FIG. 11 is a schematic sectional view illustrating an MCP having three stacked chips according to another embodiment of the present invention.

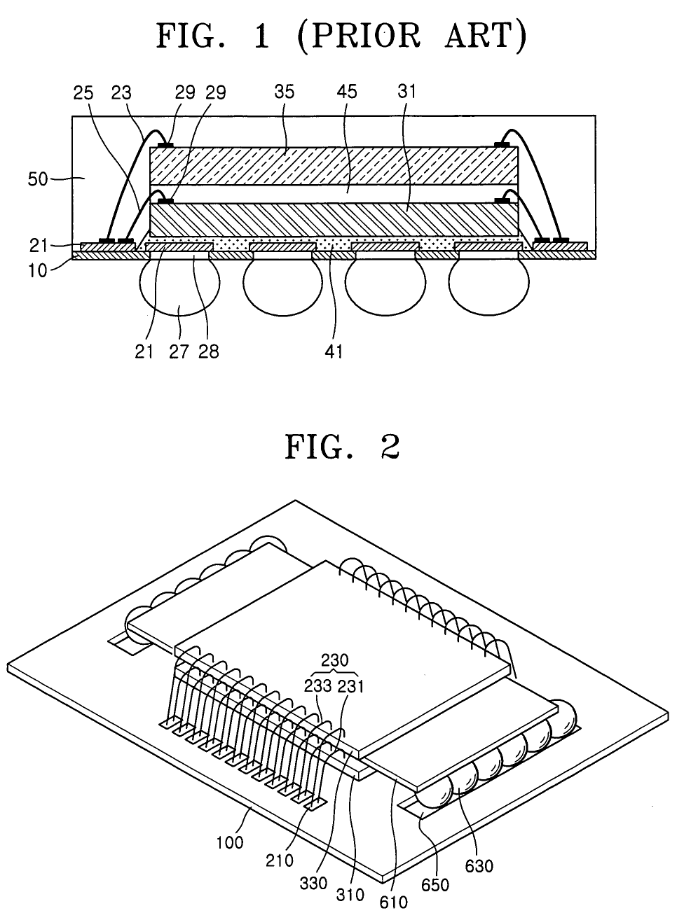

### DETAILED DESCRIPTION OF THE INVENTION

The present invention will now be described more fully with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete and will fully convey the scope of the invention to those skilled in the art.

In the embodiments of the present invention, a heat sink part made of a thermally conductive plate or foil is interposed between stacked integrated circuit (IC) chips of a multi-chip package (MCP). In one embodiment, an end portion of the heat sink part protrudes from a side of the stack of IC chips. The protrusion is thermally connected to a heat transfer pad, which is formed on a substrate supporting thereon the IC chips, through thermally connecting parts arranged along the side of the stack of IC chips. The heat transfer pad is thermally connected to solder balls that are attached to a rear surface of the substrate and function as heat dissipating parts.

Accordingly, a heat dissipating path is composed of the heat sink part, the thermally connecting parts, the heat transfer pad, and the solder balls. Heat generated in the chips, particularly, heat trapped between the chips, is effectively transferred and dissipated through the heat dissipating path. As a result, the temperature of the chips is prevented from increasing due to the trapped heat during the operation of the chips. Also, product characteristics, such as chip operating speed, refresh characteristics, life time, or resistance to wrong operation, are effectively prevented from deteriorating due to the temperature rise of the chips.

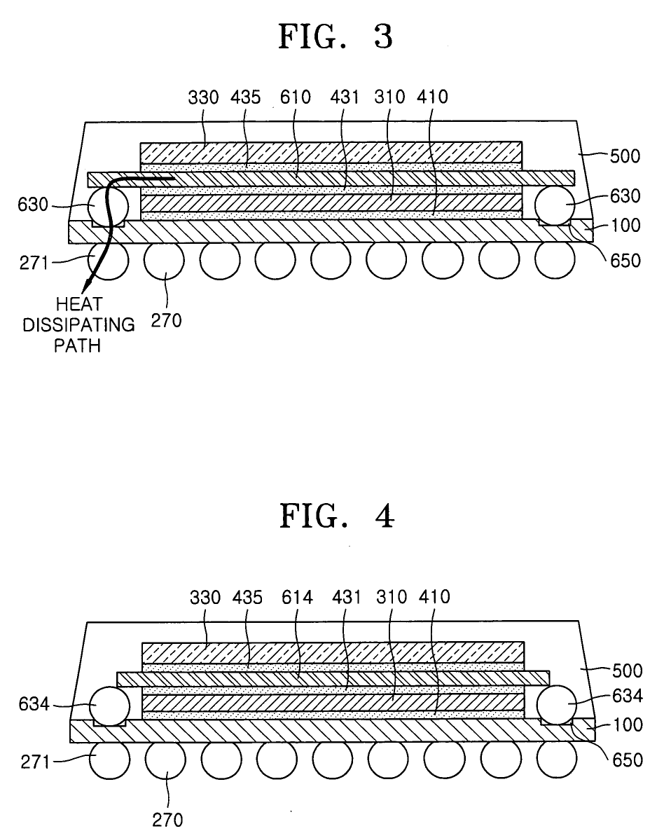

FIG. 2 is a schematic perspective view illustrating an MCP according to an embodiment of the present invention. FIG. 3 is a schematic sectional view illustrating the MCP shown in FIG. 2.

Referring to FIGS. 2 and 3, an MCP basically has at least two IC chips 310 and 330 embedded in one package. The MCP is basically provided with a substrate 100, such as a printed circuit board (PCB), as a carrier on which the chips are mounted. Substrates other than the PCB may be used as the carrier on which the chips are mounted.

Connection pads 210 for electrical connection, such as a metal line connection, are provided on the substrate 100. Heat transfer pads 650 that constitute a heat dissipating path may be formed on the substrate 100. The connection pads 210 may be electrically connected to a plurality of connecting solder balls 270, which are attached under the substrate 100, by ball pads or the like. Although not shown, the connection pads 210 and the connecting solder balls 270 may be connected using vias passing through the substrate 100.

The heat transfer pads 650 may be thermally or electrically connected to the connecting solder balls 270 and substantially corresponding grounding solder balls 271, which are attached under the substrate 100. When the heat transfer pads 650 are electrically or thermally connected to the grounding solder balls 271, the grounding solder balls 271 act as ground terminals for preventing noise generated in the chips 310 and 330 and constitute the heat dissipating path. Heat inside the package is transferred and dissipated through the heat transfer pads 650 and the grounding solder balls 271 connected to the heat transfer pads 650.

Referring to FIG. 3, the lower chip, that is, the first chip 310, is adhered to the substrate 100 by a first adhesive layer 410, and the second chip 330 is adhered to the first chip 310 by a second adhesive layer 431 and a third adhesive layer 435. A heat sink part 610 is interposed between the first chip 310 and the second chip 330. The second adhesive layer 431 and the third adhesive layer 435 are disposed over and under the heat sink part 610, respectively, so that the heat sink part 610 is attached between the chips 310 and 330.

In the meantime, bonding wires 230, such as gold wires, including first and second bonding wires 231 and 233 may be connected to the connection pads 210 to electrically connect the chips 310 and 330 to an external circuit. The first chip 310 may be electrically connected to the external circuit by the first bonding wires 231 through the connection pads 210, and the second chip 330 may be electrically connected to the external circuit by the second boding wires 233 through the connection pads 210.

A sealing part 500 to protect the stacked chips 310 and 330 and the bonding wires 230 is formed by a molding process using a sealing material, such as an epoxy molding compound (EMC).

The heat sink part 610 may be formed of a high thermally conductive plate or foil, such as a copper plate, a metal plate, a silicon plate, a metal foil, a copper foil, a silicon plate coated with a metal layer, or a silicon plate coated with a copper layer. Here, it is preferable that the heat sink part 610 is made of a flat plate or a flexible foil to prevent the chips from being cracked due to irregular pressure distribution during the chip stacking process or during the molding process.

The heat sink part 610, as shown in the embodiment of FIGS. 2 and 3, is interposed between the IC chips so that end portions of the heat sink part 610 protrude from both sides of the stack of IC chips 310 and 330. Heat collected in the heat sink part 610 is dissipated through the substrate 100, substantially through the heat transfer pads 650 on the substrate 100 and the grounding solder balls 271 connected to the heat transfer pads 650. Although not shown, the heat transfer pads 650 and the grounding solder balls 271 may be connected using vias passing through the substrate 100.

To complete the heat dissipating path, the heat sink part 610 and the heat transfer pads 650 must be thermally connected to each other. To this end, thermally connecting parts 630 are introduced to thermally connect the protruding end portions of the heat sink part 610 and the substrate 100.

The thermally connecting parts 630 may be solder balls attached on the substrate 100 and the exposed end portions of the heat sink part 610. If the thermally connecting parts 630 are solder balls, the thermally connecting parts 630 can be easily formed using a solder ball attaching system and method that are currently used in a semiconductor chip or an IC chip package.

Further, if the thermally connecting parts 630 are solder balls, when a sealing material EMC for the sealing part 500 is injected, the sealing material EMC can be sufficiently injected under the heat sink part 610. In addition, although the end portions of the heat sink part 610 protrude beyond the stack of IC chips 310 and 330, the heat sink part 610 can be supported at a uniform height by the plurality of solder balls that are the thermally connecting parts 630. As a consequence, a pressure is prevented from being irregularly applied to the end portions of the heat sink part 610, and the sealing part 500 is effectively prevented from being cracked due to the irregular pressure.

The heat dissipating path of the MCP, as shown by an arrow in the embodiment of FIG. 3, is composed of the heat sink part 610, the solder balls as the thermally connecting parts 630, the heat transfer pads 650, and the grounding solder balls 271 connected to the heat transfer pads 650. The heat dissipating path can effectively transfer and dissipate heat generated in the chips 310 and 330 since the parts constituting the heat dissipating path are all made of high thermally conductive materials.

Accordingly, heat generated during the operation of the chips 310 and 330 is prevented from accumulating or collecting between the chips 310 and 330. Therefore, a decrease in operating speed, refresh characteristics, life time, and a danger of wrong operation, which may result from the temperature rise of the chips 310 and 330 due to the heat generated during the operation of the chips 310 and 330, can be effectively prevented.

Meanwhile, the heat dissipating path as shown in FIG. 3 may be formed in various shapes when the heat sink part is made from a plate material and the thermally connecting parts are solder balls.

FIG. 4 is a schematic sectional view illustrating ball-shaped thermally connecting parts employed in an MCP according to another embodiment of the present invention.

Referring to FIG. 4, solder balls 634 may be formed as thermally connecting parts contacting tips of end portions of a heat sink part 614. The solder balls 634 as the thermally connecting parts are differently formed from the solder balls 630 as the thermally connecting parts shown in FIG. 3 that are interposed between and attached to the heat sink part 610 and the heat transfer pads 650.

Specifically, the solder balls 630 of the thermally connecting parts as shown in FIG. 3 are formed by attaching the solder balls 630 to the exposed end portions of the heat sink part 610, attaching the heat sink part 610 between the chips 310 and 330, which is performed while the stacked chips 310 and 330 are mounted on the substrate 100, and attaching the solder balls 630 on the heat transfer pads 650. That is, after the solder balls 630 are attached to the heat sink part 610, the heat sink part 610 is attached between the chips 310 and 330. In this case, it may be a little bit harder to maintain a uniform height of the heat sink part 610 when the solder balls 630 are attached to the heat sink part 610.

On the other hand, the solder balls 634 of the thermally connecting part as shown in FIG. 4 are formed by attaching the heat sink part 614 between the chips 310 and 330, which is performed while the chips 310 and 330 are stacked on the substrate 100, and attaching the solder balls 634 to the heat transfer pads 650 and the end portions of the heat sink part 614. In this case, since the heat sink part 614 is attached between the chips 310 and 330 before the solder balls 634 are attached to the heat sink part 614 and the heat transfer pads 650, it may be a little bit easier to maintain a uniform height of the heat sink part 614.

In the meantime, when the thermally connecting parts are solder balls 630 and 634, it is preferable that solder paste or flux used for solder ball mounting does not remain in the package. In this case, it is preferable that water-soluble flux is used for a user to remove remaining flux with a flux cleaner without damaging bonding pads (not shown) provided on the chips 310 and 330.

Although FIGS. 3 and 4 show that the thermally connecting parts are solder balls 630 and 634, the thermally connecting parts may also be formed by solder paste reflow instead of the solder balls.

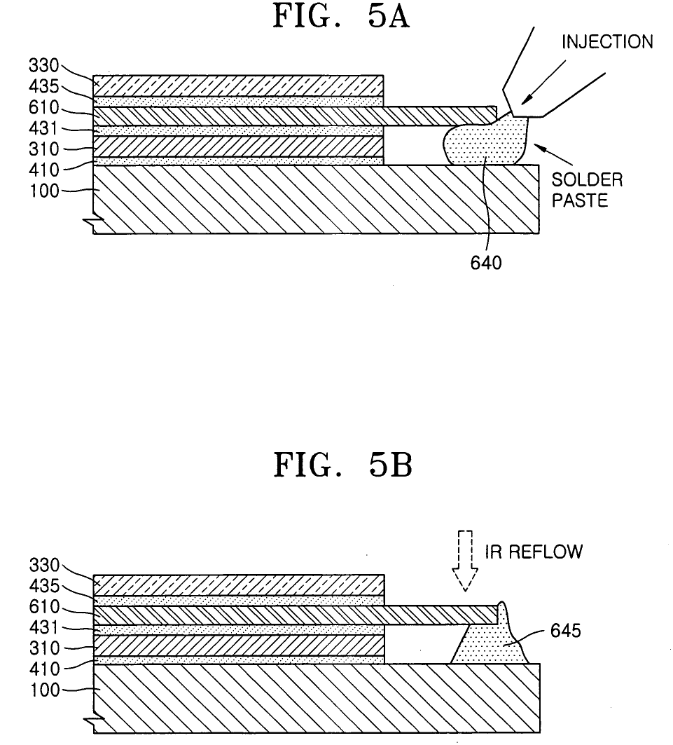

FIGS. 5A and 5B are schematic sectional views illustrating a method of forming thermally connecting parts by solder paste reflow, which are employed in an MCP according to still another embodiment of the present invention.

The thermally connecting parts may be formed by solder paste reflow rather than by solder balls. For example, as shown in FIG. 5A, a solder paste 640 is injected between the exposed end portion of the heat sink part 610 and the substrate 100, substantially between the exposed end portion of the heat sink part 610 and the heat transfer pad of the substrate 100. As shown in FIG. 5B, an infrared (IR) reflow process is performed to form solder parts 645. The solder parts 645 thermally or/and electrically connect the heat sink part 610 and the heat transfer pad of the substrate 100.

Although the thermally connecting parts may be the solder parts 645 formed by the solder paste reflow, it may be more advantageous in productivity to attach solder balls to the heat sink part 610 using a solder ball mounting device and use the attached solder balls as the thermally connecting parts. It is preferable that the heat sink part 610 has ball lands in which the solder balls are self-aligned so that the solder balls can be mounted well on the heat sink part 610.

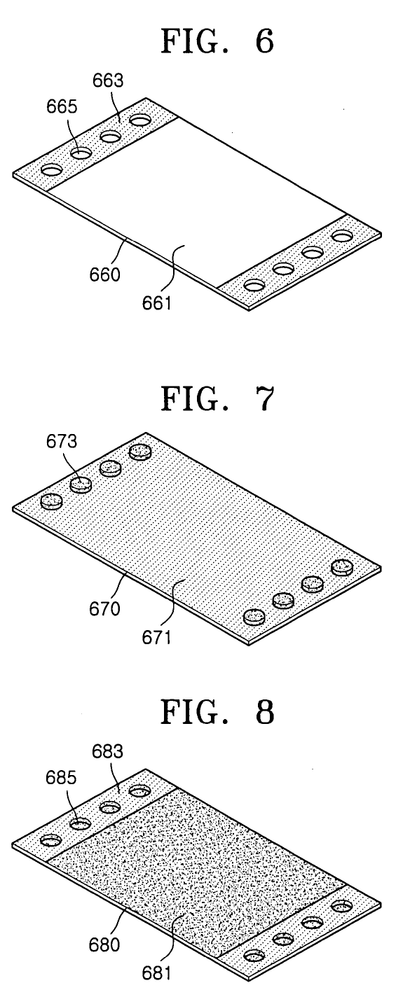

FIG. 6 is a schematic perspective view illustrating a first example of a heat sink part employed in the MCP according to an embodiment of the present invention. Referring to FIG. 6, a heat sink part 660 may have ball lands 665 formed on exposed end portions so that solder balls can be easily self-aligned when being attached to the heat sink part 660. The ball lands 665 may be made of a solder-wettable layer, for example, a copper layer.

For example, when the heat sink part 660 is made of a copper plate, solder resist films 663 are printed on the exposed end portions to open the ball lands 665. Since the solder resist films 663 do not permit solder to be attached thereto, the solder balls are self-aligned in the ball lands 665 made of copper that are opened by the solder resist films 663.

FIG. 7 is a schematic perspective view illustrating a second example of the heat sink part employed in the MCP according to another embodiment of the present invention.

Referring to FIG. 7, when a heat sink part 670 is made of a silicon plate or the like, ball lands 673 may be formed by depositing an aluminium layer 671 on the entire surface of the silicon plate and selectively depositing a copper layer on exposed end portions. The aluminium layer 671 is basically a non-wettable layer and functions as a metal layer for isolating the ball lands 673 from one another.

FIG. 8 is a schematic perspective view illustrating a third example of a heat sink part employed in the MCP according to yet another embodiment of the present invention.

Referring to FIG. 8, when a heat sink part 680 is formed of a silicon plate or the like, a copper layer 681 is deposited on the entire surface of the silicon plate and band-shaped aluminium layers 683 are formed on exposed end portions to selectively open ball lands made of copper.

Since the heat sink part 610 is a layer formed of metal (e.g., aluminium or copper) or silicon, and can be grounded to the grounding solder balls 271 through the thermally connecting parts 630 and the heat transfer pads 650, which are also used as ground pads, as described with reference to FIG. 3, the heat sink part 610 can prevent signal interference between the IC chips 310 and 330 that are disposed over and under the heat sink part 610. That is, the heat sink part 610 can effectively prevent noise in the IC chips 310 and 330.

In the meantime, the solder balls or the thermally connecting parts constituting the heat dissipating path of the MCP according to the present invention may be arranged in one, two, or more rows along a side surface of the stack of IC chips on the substrate 100.

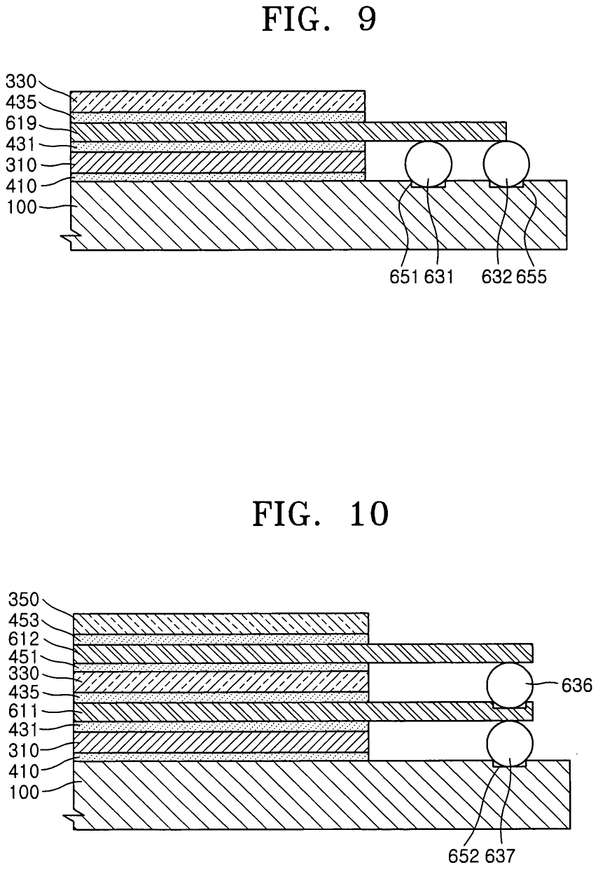

FIG. 9 is a schematic sectional view illustrating thermally connecting parts employed in an MCP according to yet another embodiment of the present invention.

Referring to FIG. 9, the thermally connecting parts that thermally connect a heat sink part 619 to the substrate 100 may be arranged in two rows. That is, as shown in FIG. 9, a first heat transfer pad 651 is formed on the substrate 100, and a second heat transfer pad 655 is formed behind the first heat transfer pad 651. A plurality of first solder balls 631 as first thermally connecting parts may be arranged to thermally or/and electrically connect the heat sink part 619 to the first heat transfer pad 651. A plurality of second solder balls 632 as second thermally connecting parts may be arranged to thermally or/and electrically connect the heat sink part 619 to the second heat transfer pad 655. The solder balls 631 and 632 as the thermally connecting parts may be arranged in one, two, or more rows along the side surface of the stacked chips on the substrate 100.

The MCP according to an embodiment of the present invention may be applied to a case where three or more chips are stacked. In this case, a plurality of heat sink parts and thermally connecting parts are accordingly provided.

FIG. 10 is a schematic sectional view illustrating an MCP having three stacked chips according to a further embodiment of the present invention.

Referring to FIG. 10, when three IC chips 310, 330, and 350 are stacked, a first heat sink part 611 is interposed between the first chip 310 and the second chip 330, and a second heat sink part 612 is attached by third adhesive layers 451 and 453 between the second chip 330 and the third chip 350.

In order to dissipate heat collected in the first heat sink part 611 and the second heat sink part 612 through the substrate 100, first thermally connecting parts 636 that thermally connect the first heat sink part 611 and the second heat sink part 612 and second thermally connecting parts 637 that thermally connect the first heat sink part 611 to the substrate 100 are employed. The first thermally connecting parts 636 and the second thermally connecting parts 637 may be solder balls substantially vertically spaced in parallel to each other, as shown in FIG. 10. In the meantime, when solder balls are used as the thermally connecting parts, heat transfer pads may be positioned inside recessed portions of the substrate 100 so that the solder balls can be easily aligned in the recessed portions and easily attached to the substrate 100. Recessed portions may also be formed on the first heat sink parts 611, so that the solder balls as the second thermally connecting part 636 can be easily aligned.

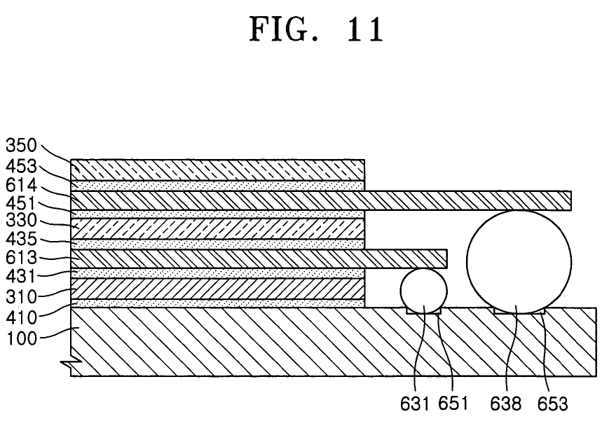

FIG. 11 is a schematic sectional view illustrating an MCP having three stacked chips according to another embodiment of the present invention.

Referring to FIG. 11, when the three chips 310, 330, and 350 are stacked, a first heat sink part 613 is interposed between the first chip 310 and the second chip 330, and a second heat sink part 614 is attached by the third adhesive layers 451 and 453 between the second chip 330 and the third chip 350.

To dissipate heat collected in the first heat sink part 613 and the second heat sink part 614 through the substrate 100, first thermally connecting parts 631 that thermally connect the first heat sink part 613 to a first heat transfer pad 651 of the substrate 100 and second thermally connecting parts 638 that thermally connect the second heat sink part 614 to a second heat transfer pad 653 of the substrate 100 may be employed. At this time, the second thermally connecting parts 638 may be solder balls larger than those of the first thermally connecting parts 631. The second heat transfer pad 653 to which the second thermally connecting parts 638 are attached is disposed behind the first heat transfer pads 651. Accordingly, the second heat sink part 614 may protrude longer than the first heat sink part 613.

The MCP according to the embodiments of the present invention may include a stack of IC chips, a plate-shaped heat sink part interposed between the IC chips so that two facing end portions of the heat sink part can protrude from both sides of the stack of IC chips, heat transfer pads formed in the vicinity of side surfaces of the stack of IC chips where the stack of IC chips is mounted and the two end portions of the heat sink part are exposed, a substrate including connection pads to which bonding wires arranged near to the other side surfaces of the stack of IC chips are connected, and a plurality of thermally connecting parts for thermally connecting the two end portions of the heat sink part to the heat transfer pads so that heat collected in the heat sink part can be dissipated through the substrate.

The MCP may include a stack of IC chips, a first heat sink part interposed between the IC chips so that one end portion of the first heat sink part can be exposed from a side of the stack of IC chips, a second heat sink part interposed between the first heat sink part and one of the IC chips so that an end portion of the second heat sink part can be exposed from the side of the stack of IC chips, a substrate on which the stack of IC chips is mounted, and thermally connecting parts for thermally connecting the exposed end portions of the heat sink parts to the substrate to dissipate heat collected in the first and second heat sink parts through the substrate.

The thermally connecting parts may include first thermally connecting parts that thermally connect the first heat sink part to the second heat sink part, and second thermally connecting parts that thermally connect the first heat sink to the substrate.

Alternatively, the thermally connecting parts may include first thermally connecting parts that thermally connect the first heat sink part to the substrate and second thermally connecting parts that thermally connect the second heat sink part to the substrate.

Further, the MCP may include a stack of IC chips, a heat sink part interposed between the IC chips so that one end portion of the heat sink part can be exposed from a side of the stack of IC chips, a substrate on which the stack of IC chips is mounted, and thermally connecting parts for thermally connecting the exposed end portion of the heat sink to ground terminals of the substrate to dissipate heat collected in the heat sink part through the ground terminals of the substrate.

The ground terminals may include a ground pad formed on the substrate to be thermally and electrically connected to the thermally connecting parts, and grounding solder balls attached to the substrate to be electrically connected to the ground pad and connected to an external circuit.

The thermally connecting parts may be solder balls attached to the exposed end portion of the heat sink part and attached on the ground pads.

The thermally connecting parts may be solder parts formed by injecting solder paste between the exposed end portion of the heat sink part and the ground pad and performing a reflow process.

As described above, since the thermally connecting parts connecting the heat sink part interposed between the stacked IC chips to the grounding solder balls attached to the rear surface of the substrate are solder parts or solder balls, a heat dissipating path through which heat between the chips is dissipated to the outside of the package can be formed.

As a result, heat generated in the chips, especially heat trapped in the chips, is transferred and dissipated to the outside effectively. Accordingly, the temperature rise of the chips during the operation of the chips is prevented, and product characteristics, such as operating speed, refresh characteristics, life time, or resistance against wrong operation can be effectively prevented from deteriorating.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A multi-chip package comprising:
a stack of integrated circuit chips;
a heat sink part interposed between the integrated circuit chips so that at least one end portion of the heat sink part can be exposed from at least a side of the stack of integrated circuit chips;
a substrate on which the stack of integrated circuit chips is mounted; and
a thermally connecting part to thermally connect the exposed end portion of the heat sink part to the substrate to dissipate heat collected in the heat sink part through the substrate.

2. The multi-chip package of claim 1, wherein the heat sink part is made of one selected from the group consisting of a copper plate, a metal plate, a silicon plate, a metal foil, a copper foil, a silicon plate coated with a metal layer, and a silicon plate coated with a copper layer.

3. The multi-chip package of claim 1, wherein the thermally connecting part comprises a solder ball attached to the exposed end portion of the heat sink part and attached on the substrate.

4. The multi-chip package of claim 1, wherein the thermally connecting part comprises a solder part formed by injecting solder paste between the substrate and the exposed end portion of the heat sink part and performing a reflow process.

5. The multi-chip package of claim 1, wherein the substrate further comprises:
a heat transfer pad connected to the thermally connecting part; and
a connecting solder ball thermally connected to the heat transfer pad and attached to the substrate to be connected to an external circuit.

6. The multi-chip package of claim 1, wherein a plurality of thermally connecting parts are arranged along at least a side of the stack of integrated circuit chips on the substrate.

7. The multi-chip package of claim 1, wherein a plurality of thermally connecting parts are arranged in at least two rows along at least a side of the stack of integrated circuit chips on the substrate near to the side of the stack of integrated circuit chips.

8. A multi-chip package comprising:
a stack of integrated circuit chips;
a heat sink part interposed between the integrated circuit chips so that at least one end portion of the heat sink part can be exposed from at least a side of the stack of integrated circuit chips;
a substrate having ground terminals and supporting thereon the stack of integrated circuit chips; and
thermally connecting parts to thermally connect the exposed end portion of the heat sink part to the ground terminals of the substrate to dissipate heat collected in the heat sink part through the ground terminals of the substrate.

9. The multi-chip package of claim 8, wherein the ground terminals comprise:
a ground pad formed on the substrate to be thermally and electrically connected to the thermally connecting parts; and
grounding solder balls electrically connected to the ground pad and attached to the substrate to be connected to an external circuit.

10. The multi-chip package of claim 9, wherein the thermally connecting parts comprise solder balls attached to the exposed end portion of the heat sink and attached on the ground pad.

11. The multi-chip package of claim 9, wherein the thermally connecting parts comprise solder parts formed by injecting solder paste between the exposed end portion of the heat sink and the ground pad and performing a reflow process.

12. A multi-chip package comprising:
a stack of integrated circuit chips having a first set of sides and a second set of sides;
a plate-shaped heat sink part interposed between the integrated circuit chips, the heat sink part having two end portions that extend beyond the first set of sides of the stack of integrated circuit chips;
a substrate including heat transfer pads formed in the vicinity of the first set of side surfaces of the stack of integrated circuit chips where the stack of integrated circuit chips is mounted and the two end portions of the heat sink part are exposed, and connection pads connected to bonding wires arranged near to the second set of sides of the stack of integrated circuit chips; and
a plurality of thermally connecting parts to thermally connect the two end portions of the heat sink part to the heat transfer pads to dissipate heat collected in the heat sink part through the substrate.

13. The multi-chip package of claim 12, wherein the heat sink part is a plate or foil made of one selected from the group consisting of copper, metal, and silicon.

14. The multi-chip package of claim 12, wherein the thermally connecting parts comprise solder balls attached to the exposed end portions of the heat sink part and attached to the heat transfer pads.

15. The multi-chip package of claim 14, wherein the end portions of the heat sink part have ball lands selectively opened so that the solder balls can be self-aligned and attached to the end portions.

16. The multi-chip package of claim 15, wherein the ball lands are open copper areas surrounded by an aluminum layer.

17. The multi-chip package of claim 14, wherein the heat sink part comprises:
a copper plate; and
a printed solder resist film formed on the end portions of the copper plate and open ball lands on a surface of the copper plate so that the solder balls can be self-aligned and selectively attached to the end portions.

18. The multi-chip package of claim 14, wherein the heat sink part comprises:
a silicon plate;
an aluminum layer deposited on the silicon plate; and
a copper layer deposited on the end portions of the silicon plate and including ball lands in which the solder balls are self-aligned and selectively attached to the end portions.

19. The multi-chip package of claim 14, wherein the heat sink part comprises:
a silicon plate;
a copper layer deposited on the silicon plate; and
an aluminum layer selectively deposited on the copper layer at the end portions of the silicon plate and open ball lands on a surface of the copper layer so that the solder balls can be self-aligned and selectively attached to the end portions.

20. The multi-chip package of claim 12, wherein the thickness of the heat sink part ranges from 50 to 120 μm.

21. The multi-chip package of claim 12, wherein the thermally connecting parts are solder parts formed by injecting solder paste between the exposed end portions of the heat sink part and the heat transfer pads and performing a reflow process.

22. The multi-chip package of claim 12, wherein the substrate further comprises connecting solder balls attached to the substrate to be connected to an external circuit,
wherein the heat transfer pads are electrically and thermally connected to grounding solder balls among the connecting solder balls.

23. The multi-chip package of claim 12, wherein the thermally connecting parts are arranged in two rows along the first set of sides of the stack of integrated circuit chips on the substrate near to the sides of the stack of integrated circuit chips.

24. A multi-chip package comprising:
a stack of integrated circuit chips;
a first heat sink part interposed between the integrated circuit chips so that one end portion of the first heat sink part can be exposed from a side of the stack of integrated circuit chips;
a second heat sink part interposed between the first heat sink part and one integrated circuit chip so that an end portion of the second heat sink part can be exposed from the side of the stack of integrated circuit chips;
a substrate on which the stack of integrated circuit chips is mounted; and
thermally connecting parts to thermally connect the exposed end portions of the first and second heat sink parts to the substrate to dissipate heat collected in the first and second heat sink parts through the substrate.

25. The multi-chip package of claim 24, wherein the thermally connecting parts comprise:
first thermally connecting parts that thermally connect the first heat sink part to the second heat sink part; and
second thermally connecting parts that thermally connect the first heat sink part to the substrate.

26. The multi-chip package of claim 24, wherein the thermally connecting parts comprise:
first thermally connecting parts that thermally connect the first heat sink part to the substrate; and
second thermally connecting parts that thermally connect the second heat sink part to the substrate.
